(19) United States
(12) Patent Application Publication
(10) Pub. No.: US 2021/0143153 A1
(43) Pub. Date: May 13, 2021

(54) FIN FIELD-EFFECT TRANSISTOR (FET) (FINFET) CIRCUITS EMPLOYING REPLACEMENT N-TYPE FET (NFET) SOURCE/DRAIN (S/D) TO AVOID OR PREVENT SHORT DEFECTS AND RELATED METHODS OF FABRICATION

(71) Applicant: QUALCOMM Incorporated, San Diego, CA (US)

(72) Inventors: Kwanyong Lim, San Diego, CA (US); Hyunwoo Park, San Diego, CA (US); Youn Sung Choi, San Diego, CA (US); Youseok Suh, San Diego, CA (US)

(21) Appl. No.: 16/682,788

(22) Filed: Nov. 13, 2019

(51) Int. Cl. H01L 27/092; H01L 29/78; H01L 29/66; H01L 21/8238

(52) U.S. Cl. CPC H01L 27/0924; H01L 29/785; H01L 29/66545; H01L 21/823871; H01L 21/823821; H01L 21/823814; H01L 29/66795

(57) ABSTRACT

Fin Field-Effect Transistor (FET) (FinFET) circuits employing a replacement N-type FET (NFET) source/drains (S/D) are disclosed. The disclosed method for forming a FinFET circuit includes forming two P-type epitaxial S/Ds (epi-S/Ds), one on the fin in the P-type diffusion region and one on the fin in the N-type diffusion region, forming a boundary layer to isolate the P-type epi-S/Ds, and then replacing the P-type epi-S/D under the boundary layer in the N-type diffusion region with an N-type epi-S/D. A mask is employed in steps for replacing the P-type epi-S/D with an N-type epi-S/D in the disclosed method but differs from the mask in the previous method such that vulnerability to variations thereof is reduced. The mask in the disclosed method has a larger acceptable range of variation within which no defects are created, so the disclosed method is less vulnerable to process variation and prevents short defects.

### BACKGROUND

### I. Field of the Disclosure

The field of the disclosure relates to transistors, such as Fin Field-Effect Transistors (FETs) (FinFETs) in integrated circuits (ICs) and, more particularly, to avoiding short defects when forming a circuit with an N-type FET (NFET) and a P-type FET (PFET).

### II. Background

Transistors are essential components employed in large numbers in components of electronic devices. For example, integrated circuit (IC) components such as central processing units (CPUs), digital signal processors (DSPs), and memory systems each employ a large quantity of transistors in logic circuits and memory devices. As the functions of electronic devices become more complex, the number of transistors needed to perform such functions increases. Simultaneously, there is demand for electronic devices, such as mobile devices, to be smaller in size which requires the ICs controlling such devices to be smaller. To fit increasingly more transistors into an even smaller space, the dimensions of transistors in the ICs need to be smaller.

In this regard, three-dimensional transistors have been developed to reduce the area occupied by a transistor on an IC. A Fin Field-Effect Transistor (FET) (FinFET) is one type of three-dimensional transistor in which one or more semiconductor fins extend vertically from a substrate. The semiconductor fins are doped to have either a P-type or an N-type. Complementary metal-oxide semiconductor (CMOS) circuits and other circuits employ both P-type and N-type FinFETs in close proximity to each other. To fit the respective FinFETs in a minimum area, the distance between fins of P-type FETs (PFETs) and fins of N-type FETs (NFETs) in a circuit must be minimized and such distance continues to get smaller. However, existing fabrication processes are vulnerable to process variations that can result in defects causing electrical shorts when an NFET is formed beside a PFET. Short defects cause the circuit to fail, which reduces yield, and increases the cost of fabrication.

### SUMMARY OF THE DISCLOSURE

Aspects disclosed herein include Fin Field-Effect Transistor (FET) (FinFET) circuits employing replacement N-type FET (NFET) source/drain (S/D) to avoid or prevent short defects. Related methods of fabrication are also disclosed. Fabrication of the FinFET circuit may include an NFET being formed in an N-type diffusion region of a substrate substantially parallel to a PFET formed in a P-type diffusion region of the substrate. During conventional fabrication, a P-type epitaxial S/D (epi-S/D) is grown on a recessed fin in the P-type diffusion region first while a fin in the N-type diffusion region is isolated. A mask is employed to isolate the P-type epi-S/D while the fin in the N-type diffusion region is recessed and an N-type epi-S/D is grown thereon. A small variation of the mask coverage can cause a portion of the P-type epi-S/D to be exposed. As a result, during a process of forming the N-type epi-S/D on the fin in the N-type diffusion region, there is no barrier to prevent N-type epi material from also forming on the exposed portion of the P-type epi-S/D. The additional growth of N-type epi material on the exposed portion of the P-type epi-S/D can cause an electrical short to the N-type epi-S/D.

The method disclosed herein reduces vulnerability to mask variation by an exemplary process in which a barrier to formation of N-type epi material on the P-type epi-S/D is provided. In the disclosed method, P-type epi-S/Ds are initially formed on both of the fin in the P-type diffusion region and the fin in the N-type diffusion region and a boundary layer is formed over both of the P-type epi-S/Ds, isolating them from each other. A mask is employed in a process for removing a portion of the boundary layer in only the N-type diffusion region, exposing a portion of the P-type epi-S/D therein. The exposed P-type epi-S/D is removed from within the remaining structure of the boundary layer in the N-type diffusion region and is replaced by an N-type epi-S/D formed on the recessed fin therein. By forming the N-type epi-S/D within the remaining structure of the boundary layer, a barrier to formation of short defects (i.e., from the P-type epi-S/D to the N-type epi-S/D) due to mask variation is provided. The mask employed for removing the portion of the boundary layer has a much larger acceptable range of variation, within which no defects are created, than the mask of the conventional method, so the disclosed method is less vulnerable to process variation and avoids or prevents short defects.

In this regard, in one aspect, a FinFET circuit is disclosed. The FinFET circuit includes a first fin extending from a substrate in a P-type region of the substrate, a second fin extending from the substrate in an N-type region of the substrate, the second fin substantially parallel to the first fin, a P-type epi-S/D on the first fin, and an N-type epi-S/D on the second fin, an Inter-Layer Dielectric (ILD) material over the P-type epi-S/D and the N-type epi-S/D, a boundary layer having a thickness between the ILD material and the P-type epi-S/D and having the thickness between the ILD material and the N-type epi-S/D.

In another aspect, a method of forming an epi-S/D of an N-type FinFET substantially parallel to an epi-S/D of a P-type FinFET in a FinFET circuit is disclosed. The method includes forming a first fin extending from a P-type region of a substrate and a second fin, substantially parallel to the first fin, extending from an N-type region of the substrate, forming a first P-type epi-S/D on the first fin and a second P-type epi-S/D on the second fin, forming a boundary layer on the first P-type epi-S/D and on the second P-type epi-S/D, removing a portion of the boundary layer to expose a portion of the second P-type epi-S/D, removing the second P-type epi-S/D from within a remaining structure of the boundary layer above the second fin, and forming an N-type epi-S/D on the second fin within the remaining structure of the boundary layer above the second fin.

### BRIEF DESCRIPTION OF THE FIGURES

FIG. 1 is a plan view of a Fin Field-Effect Transistor (FET) (FinFET) circuit formed on a substrate with a P-type FET (PFET) in a P-type diffusion region and an N-type FET (NFET), substantially parallel to the PFET, in an N-type diffusion region of the substrate;

FIG. 2 is a cross-sectional view in a fabrication stage of a circuit in a conventional method of forming an N-type epitaxial (epi) source/drain (S/D) (epi-S/D) on a fin in an N-type diffusion region of a substrate substantially parallel to a fin in a P-type diffusion region of the substrate on which a P-type epi-S/D is previously grown, and illustrates an acceptable range of variation of a mask coverage for isolating the P-type epi-S/D during formation of the N-type epi-S/D;

FIGS. 3A-1 and 3A-2 are cross-sectional views of sequential fabrication stages of the circuit, subsequent to the fabrication stage in FIG. 2, of forming an N-type epi-S/D on a fin next to a P-type epi-S/D with a mask coverage in an acceptable range of variation;

FIGS. 3B-1 and 3B-2 illustrate cross-sectional views of sequential fabrication stages of the circuit, subsequent to the fabrication stage in FIG. 2, of forming an N-type epi-S/D on a fin next to a P-type epi-S/D, and creation of a short defect due to a mask coverage outside an acceptable range of variation;

FIG. 4A illustrates a cross-section of a fabrication stage of a circuit in an exemplary process of forming P-type epi-S/Ds on both of a fin in an N-type diffusion region and a fin in a P-type diffusion region, forming a boundary layer over the P-type epi-S/Ds to isolate them, exposing the P-type epi-S/D in the N-type diffusion region, and replacing the exposed P-type epi-S/D with an N-type epi-S/D, such that a barrier to formation of short defects is provided by a remaining structure of the boundary layer;

FIG. 4B illustrates a cross-sectional view of the circuit in FIG. 4A after formation of an inter-layer dielectric (ILD) and an electrical contact to the N-type epi-S/D;

FIG. 5 is a flowchart illustrating an exemplary process of fabricating a FinFET circuit by forming P-type epi-S/Ds on both of a fin in an N-type diffusion region and a fin in a P-type diffusion region, forming a boundary layer over the P-type epi-S/Ds to isolate them, exposing the P-type epi-S/D in the N-type diffusion region and replacing the P-type epi-S/D with an N-type epi-S/D, such that a barrier to formation of short defects is provided by a remaining structure of the boundary layer;

FIGS. 6A and 6B are a flowchart illustrating an exemplary process in one embodiment disclosed herein of fabricating a FinFET circuit, such as the circuit in FIGS. 4B and 7T, by replacing a previously formed P-type epi-S/D with an N-type epi-S/D;

FIGS. 7A-7T each illustrate plan views and corresponding cross-sectional views of the circuit in FIG. 4B in respective fabrication stages of an exemplary process for forming an N-type epi-S/D on a fin in an N-type diffusion region by replacing a P-type epi-S/D formed on the fin wherein steps employ a mask having a reduced vulnerability to process variation such that short defects are prevented;

FIGS. 8A-8F illustrate cross-sectional views of fabrication stages of a circuit including a PFET and a substantially parallel NFET according to conventional methods, and FIG. 8G is the circuit in FIG. 4B provided side-by-side with FIG. 8F for purposes of comparison to explain the structural distinctions of the FinFET circuit fabricated with reduced vulnerability to mask variation afforded by an exemplary process disclosed herein;

FIGS. 9A and 9B are a flowchart of another exemplary process of fabricating the circuit in FIG. 10Q by replacing a previously formed P-type epi-S/D with an N-type epi-S/D;

FIGS. 10A-10Q illustrate plan views and corresponding cross-sectional views of a circuit in respective fabrication stages in the exemplary process illustrated in the flowcharts in FIGS. 9A and 9B of forming an N-type epi-S/D on a fin in an N-type diffusion region by replacing a P-type epi-S/D formed on the fin wherein steps employ a mask having a reduced vulnerability to process variation such that short defects are prevented;

FIGS. 1A and 11B are a cross-sectional view of the circuit formed according to the fabrication stages illustrated in FIGS. 8A-8G, and a cross-sectional views of the circuit formed according to the fabrication stages illustrated in FIGS. 10A-10Q provided side-by-side for comparison;

FIG. 12 is a block diagram of an exemplary processor-based system that can include an IC including a circuit as illustrated in FIGS. 4B, 7T, and 10Q wherein an NFET is formed substantially parallel to a PFET by one of the exemplary processes illustrated in FIGS. 7A-7T and 10A-10Q; and

FIG. 13 is a block diagram of an exemplary wireless communications device that includes radio frequency (RF) components formed from an IC, wherein any of the components therein can include an IC including a circuit as illustrated in FIGS. 4B, 7T, and 10Q with an NFET formed substantially parallel to a PFET by one of the exemplary processes illustrated in FIGS. 7A-7T and 10A-10Q.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include Fin Field-Effect Transistor (FET) (FinFET) circuits employing replacement N-type FET (NFET) source/drain (S/D) to avoid or prevent short defects. Related methods of fabrication are also disclosed. Fabrication of the FinFET circuit may include an NFET being formed in an N-type diffusion region of a substrate substantially parallel to a PFET formed in a P-type diffusion region of the substrate. During conventional fabrication, a P-type epitaxial S/D (epi-S/D) is grown on a recessed fin in the P-type diffusion region first while a fin in the N-type diffusion region is isolated. A mask is employed to isolate the P-type epi-S/D while the fin in the N-type diffusion region is recessed and an N-type epi-S/D is grown thereon. A small variation of the mask coverage can cause a portion of the P-type epi-S/D to be exposed. As a result, during a process of forming the N-type epi-S/D on the fin in the N-type diffusion region, there is no barrier to prevent N-type epi material from also forming on the exposed portion of the P-type epi-S/D. The additional growth of N-type epi material on the exposed portion of the P-type epi-S/D can cause an electrical short to the N-type epi-S/D.

The method disclosed herein reduces vulnerability to mask variation by an exemplary process in which a barrier to formation of N-type epi material on the P-type epi-S/D is provided. In the disclosed method, P-type epi-S/Ds are initially formed on both of the fin in the P-type diffusion region and the fin in the N-type diffusion region and a boundary layer is formed over both of the P-type epi-S/Ds, isolating them from each other. A mask is employed in a process for removing a portion of the boundary layer in only the N-type diffusion region, exposing a portion of the P-type epi-S/D therein. The exposed P-type epi-S/D is removed from within the remaining structure of the boundary layer in the N-type diffusion region and is replaced by an N-type epi-S/D formed on the recessed fin therein. By forming the N-type epi-S/D within the remaining structure of the boundary layer, a barrier to formation of short defects (i.e., from the P-type epi-S/D to the N-type epi-S/D) due to mask variation is provided. The mask employed for removing the portion of the boundary layer has a much larger acceptable range of variation, within which no defects are created, than the mask of the conventional method, so the disclosed method is less vulnerable to process variation and avoids or prevents short defects.

Before discussing an embodiment of the exemplary process of forming FinFET circuits herein, a conventional method is first disclosed with reference to FIGS. 1 to 3B-2. FIG. 1 is an illustration of a plan view of a FinFET circuit 100 including first fins 102 and second fins 104 having longitudinal axes Al_{A}-Al_{D} extending substantially parallel to each other in a first direction. The first fins 102 and second fins 104 are also referred to herein as the fins 102 and the fins 104, respectively. The fins 102 and 104 are provided in P-type diffusion region 106 and N-type diffusion regions 108, respectively, of a substrate 110. The FinFET circuit 100 in FIG. 1 is shown in a stage of fabrication before PFETs and NFETs have been formed in the fins 102 and 104 and after which the exemplary processes disclosed herein distinguish from conventional methods. After the fins 102 and 104 are formed in the substrate 110, a shallow trench isolation (STI) 112 is formed on the substrate 110 between the fins 102 and 104. Dummy gates 114 have been formed over the P-type fins 102 and N-type fins 104 in FIG. 1 to isolate channel regions 116 of the PFETs and NFETs that will be formed in the fins 102 and 104 during formation of epi-S/Ds.

In conventional methods of fabricating the FinFET circuit 100 in FIGS. 2 to 3B-2, explained in detail below, a process for forming an epi-S/D on each of the fins 102 and 104 begins by first forming P-type epi-S/Ds on the fins 102, and then forming N-type epi-S/Ds on the fins 104. FIG. 2 is a cross-sectional view of the fin 102 and the fin 104 taken at line Z-Z′ in FIG. 1 at an intermediate fabrication stage after the fin 102 in the P-type diffusion region 106 is recessed and a P-type epi-S/D 202 is formed thereon. The fabrication stage in FIG. 2 is prior to an N-type epi-S/D being formed on fin 104 in the N-type diffusion region 108. Before formation of the P-type epi S/D 202, which may be epitaxial silicon-germanium (eSiGe), for example, a gate spacer 204 was formed over the fin 104 in the N-type diffusion region 108, isolating the fin 104 during formation of the P-type epi-S/D 202. After formation of the P-type epi-S/D 202, a blocking layer 206, such as silicon nitride (SiN), for example, is formed over the P-type epi-S/D 202 and the gate spacer 204 on the fin 104. A mask 208 is employed to isolate the P-type epi-S/D 202 before the blocking layer 206 and gate spacer 204 are removed from the fin 104 and the fin 104 is recessed prior to formation of an N-type epi-S/D on the recessed fin 104. An end surface 210 of the mask 208 corresponds to dashed line D2 between dashed lines D1 and D3 in FIG. 2, where D1 is aligned with an end point of the blocking layer 206 on the P-type epi-S/D 202, and D3 is aligned with the blocking layer 206 on the fin 104. The dashed lines D1-D3 in FIG. 2 indicate an acceptable range of variation of the end surface 210. Thus, from the center dashed line D2, the maximum acceptable variation in one direction is, for example, the short distance 212 from dashed line D2 to dashed line D1. In this context, an acceptable range of variation of the end surface 210 is a range in which defects are not created. The short distance 212 causes the conventional method to be vulnerable to any minor variations exceeding such distance. For example, if the end surface 210 of the mask 208 is aligned to the right side of the dashed line D3, extending over the blocking layer 206 on the fin 104, residual portions of the blocking layer 206 may not be removed prior to forming the N-type epi-S/D. Such residual portions may interfere with formation of the N-type epi-S/D region. If the end surface 210 of the mask 208 is aligned to the left side of the dashed line D1, overlapping on the blocking layer 206 on the P-type epi-S/D 202, a portion of the P-type epi-S/D 202 may be exposed when the fin 104 is recessed. As a result, a short defect may be created on the exposed portion of the P-type epi-S/D while forming the N-type epi-S/D, as described above and in more detail below.

FIGS. 3A-1 and 3A-2 are cross-sectional views illustrating fabrication stages of the conventional method of fabrication of the FinFET circuit 100 subsequent to FIG. 2, in which the end surface 210 is aligned with the dashed line D2, as an example. In FIG. 3A-1, the blocking layer 206 and the gate spacer 204 have been removed from areas not covered by the mask 208, and the fin 104 has been recessed down to the STI 112. In FIG. 3A-2, the mask 208 has been removed and an N-type epi-S/D 302 is formed on the fin 104. The blocking layer 206 provides a barrier to growth of N-type epi material on the P-type epi-S/D 202.

FIGS. 3B-1 and 3B-2 are cross-sectional views illustrating fabrication stages of the FinFET circuit 100 subsequent to FIG. 2 in which the end surface 210 is aligned with the dashed line D1, as an example. In addition, the P-type epi-S/D 202 formed on the fin 102 is larger than in FIG. 3A-1 due to a variation in the growth of epitaxial material. As in FIG. 3A-1, the blocking layer 206 and the gate spacer 204 have been removed in areas not covered by the mask 208, and the fin 104 has been recessed down to the STI 112. In FIG. 3B-1, however, with the larger P-type epi-S/D 202 and an alignment of the end surface 210 of the mask 208 with dashed line D1 due to a small process variation, an end point of the blocking layer 206 on the P-type epi-S/D 202 was not covered by the mask 208. Consequently, the portion of the blocking layer 206 not covered by the mask 208 was removed, and a portion 304 of the P-type epi-S/D 202 is exposed.

In FIG. 3B-2, the N-type epi-S/D 302 has been formed on the fin 104. In addition, N-type epi material 306 has also been formed on the exposed portion 304 of the P-type epi-S/D 202. The N-type epi material 306 coming into contact with the N-type epi-S/D 302 creates an electrical short between the P-type epi-S/D 202 and the N-type epi-S/D 302. The N-type epi material 306 is a defect in the FinFET circuit 100 that will prevent the FinFET circuit 100 from functioning as intended. Such defects cause the circuit to fail, reducing yield in the fabrication, which increases cost. FIGS. 3B-1 and 3B-2 illustrate that the conventional fabrication process is vulnerable to small variation in the alignment of the end surface 210 of the mask 208.

FIG. 4A is an illustration of a cross-sectional view of a FinFET circuit 400 according to an embodiment of the fabrication process disclosed herein. FIG. 4A illustrates an intermediate fabrication stage of an exemplary process of fabricating the FinFET circuit 400 wherein vulnerability to short defects due to mask variation is reduced by providing a barrier to formation of N-type epi material on the P-type epi-S/D. Here, a P-type epi-S/D (not shown) is initially formed on the fin 402 in the N-type diffusion region 404, and the P-type epi-S/D 406 is formed on the fin 408 in the P-type diffusion region 410. A protective layer 412, also referred to as boundary layer 412 in FIG. 4A, is formed over both of the P-type epi-S/Ds (P-type epi-S/D 406 and the P-type epi-S/D not shown) isolating them from each other. A mask 414 is employed to remove a portion of the boundary layer 412 from only the N-type diffusion region 404, exposing a portion of the P-type epi-S/D therein. The exposed P-type epi-S/D is removed from within the remaining structure 412R of the boundary layer 412 in the N-type diffusion region 404 and the P-type epi-S/D is replaced by an N-type epi-S/D 416 (see FIG. 4B) formed on the recessed fin 402 in the remaining structure 412R. By forming the N-type epi-S/D 416 in this manner, the remaining structure 412R of the boundary layer 412 provides a barrier to formation of short defects (i.e., from the P-type epi-S/D 406 to the N-type epi-S/D 416) due to variation of the mask 414. The mask 414 employed for removing the portion of the boundary layer 412 in the N-type diffusion region 404 has a much larger acceptable range of variation (i.e., from D4 to D6, as explained below), within which no defects are created, than the mask of the conventional method, such that the disclosed method is less vulnerable to process variation.

To progress from the FinFET circuit 100 shown in FIG. 1 to the FinFET circuit 400 shown in the intermediate fabrication stage shown in FIG. 4A, a P-type epi-S/D 406 is formed on a fin 408 after the fins 408 and 402 are recessed, and a P-type epi-S/D (not shown) is also formed on the fin 402. The protective layer 412 is formed over the P-type epi-S/D 406 on the fin 408 and over the P-type epi (not shown) on the fin 402. The mask 414 is formed over the protective layer 412. An end surface 414E is aligned with the dashed line D5. In the area above fin 402 not covered by the mask 414 (i.e., to the right side of the dashed line D5), a portion of the protective layer 412 on an upper side of the P-type epi-S/D (not shown) was removed and, subsequently, the not shown P-type epi-S/D was removed (e.g., by selective etching) from within the remaining structure 412R of the protective layer 412. The dashed lines D4-D6 in FIG. 4A illustrate the acceptable range of variation of the coverage provided by the mask 414. That is, as long as the end surface 414E of the mask 414 is aligned between the dashed line D4 and the dashed line D6, no defects will be created by the disclosed exemplary process. Thus, from the center dashed line D5, the maximum acceptable variation in one direction, for example, the distance 418 from dashed line D5 to dashed line D4, is much larger than the distance 212 between the dashed lines D1 and D2 in FIG. 2. Thus, the exemplary process disclosed herein is less vulnerable to mask variation and avoids or prevents short defects.

FIG. 4B illustrates a cross-sectional view of the FinFET circuit 400 in FIG. 4A in a fabrication stage after FIG. 4A. Here, the N-type epi-S/D 416 is formed on the fin 402 in the remaining structure 412R of the protective layer 412. After formation of the N-type epi-S/D 416, an etch stop layer 422 is formed over the protective layer 412 and over the portion of the N-type epi-S/D 416 that is not covered by the protective layer 412. In FIG. 4B, the protective layer 412 in combination with the etch stop layer 422 may be referred to as a boundary layer 424 having a first thickness 424T in the FinFET circuit 400. An inter-layer dielectric (ILD) 426 is formed over the etch stop layer 422, and electrical contacts 427 are formed within the ILD 426 to provide external connections to the P-type epi-S/D 406, formed in P-type diffusion region 410 of substrate 428, and the N-type epi-S/D 416 formed in the N-type diffusion region 404.

FIG. 5 is a flowchart illustrating an exemplary process 500 of fabricating a FinFET circuit, such as the FinFET circuit 400 in FIG. 4B, wherein vulnerability to short defects due to mask variation is reduced by providing a barrier to formation of N-type epi material on the P-type epi-S/D. The process 500 is directed to forming the N-type epi-S/D 416 on the fin 402 substantially parallel to the P-type epi-S/D 406 on the fin 408 in the FinFET circuit 400. The process 500 includes forming the first fin 408 extending from the P-type diffusion region 410 of the substrate 428 and the second fin 402, substantially parallel to the first fin 408, extending from the N-type diffusion region 404 of the substrate 428 (block 502). The process 500 includes forming the first P-type epi-S/D 406 on the first fin 408 and the second P-type epi-S/D on the second fin 402 (block 504). The process 500 further includes forming the boundary layer 412 on the first P-type epi-S/D 406 and on the second P-type epi-S/D (block 506). The process 500 further includes removing a portion of the boundary layer 412 to expose a portion of the second P-type epi-S/D (block 508). The process 500 includes removing the second P-type epi-S/D from within the remaining structure 412R of the boundary layer 412 above the second fin 402 (block 510), and forming the N-type epi-S/D 416 on the second fin 402 within the remaining structure 412R of the boundary layer 412 above the second fin 402 (block 512).

FIGS. 6A and 6B are a flowchart illustrating an exemplary process 600, which is a particular aspect of the process 500 in FIG. 5. The process 600 is described below with reference to fabrication stages of a FinFET circuit 700 illustrated in FIGS. 7A-7T. Each of the FIGS. 7A-7T includes an illustration of a plan view of the FinFET circuit 700, similar to the plan view of the FinFET circuit 100 in FIG. 1, and at least one illustration of a cross-sectional view of a portion of the FinFET circuit 700, similar to FIG. 4B. FIGS. 7A-7T illustrate respective fabrication stages of the FinFET circuit 700, which corresponds to the FinFET circuit 400 in FIG. 4B, according to the process 600. The FinFET circuit 700 may be, for example, a static random access memory (SRAM) bit circuit, a complementary metal-oxide semiconductor (CMOS) logic circuit, or other type of circuit including both PFETs and NFETs. The FinFET circuit 700 may be part of a larger circuit (not shown).

FIG. 7A illustrates a fabrication stage of forming a first fin 702 extending from a P-type diffusion region 704 of a substrate 706 and a second fin 708, substantially parallel to the first fin 702, extending from an N-type diffusion region 710 of the substrate 706 (block 602). A STI 712 covers the substrate 706 beside and between the fins 702 and 708. The cross-sectional view in FIG. 7A is taken at the cross-section A-A′ of the plan view in FIG. 7A of the FinFET circuit 700, which is similar to the FinFET circuit 100 in FIG. 1. The plan view in FIG. 7A includes a second P-type fin 702′ in the P-type diffusion region 704 and a second N-type fin 708′ in the N-type diffusion region 710. The STI 712 is formed on top of the substrate 706 and beside the first fin 702 and the second fin 708.

Fins 708, 702, 702′, and 708′ extend along respective longitudinal axes A7_{A}-A7_{D} in a first direction substantially parallel to each other, as shown in FIG. 7B. FIG. 7B illustrates a fabrication stage at which dummy gates 714 have been formed over the fins 702 and 708 and on portions of the STI 712 in FIG. 7A. The dummy gates 714 are formed along longitudinal axes A7_{E} and A7_{F}, which are orthogonal to the longitudinal axes A7_{A}-A7_{B} of fins 708 and 702. The dummy gates 714 isolate channel regions 702C and 708C of the fins 702 and 708 that will become channel regions of PFETs and NFETs formed in the fins 702 and 708. The cross-sectional views in FIG. 7B are taken at lines B1-B1′ and B2-B2′, respectively, in the plan view of FIG. 7B. As shown in the cross-section at line B1-B1′, the dummy gate 714 may include multiple layers. In the example shown in FIG. 7B, the dummy gate 714 includes an oxide 716 formed directly on the fins 702 and 708 and on the STI 712. The dummy gate 714 also includes a dummy layer 718, such as polysilicon, formed over the oxide 716. A hard mask 720, which may be SiN, is formed over the dummy layer 718. At the cross-section at line B2-B2′, no dummy gate 714 is formed over the fins 702 and 708 and the STI 712.

At the fabrication stage shown in FIG. 7C, a gate spacer 722 is deposited over the FinFET circuit 700 in FIG. 7B. As shown in the cross-sectional view in FIG. 7C, taken at line C-C′ in the plan view in FIG. 7C, the gate spacer 722 covers the first fin 702 and the second fin 708. The gate spacer 722 is a layer formed on vertical and horizontal surfaces of structures in the FinFET circuit 700. The gate spacer 722 formed on side walls 714W of the dummy gates 714 is employed for replacing the dummy gates 714 with conductive gates in a subsequent fabrication stage.

In the fabrication stage illustrated in FIG. 7D, the gate spacer 722 is removed (e.g., etched away) from horizontal surfaces of the FinFET circuit 700 in FIG. 7C and remains on the side walls 714W of the dummy gates 714. The cross-sectional view taken at line D-D′ of the plan view in FIG. 7D shows that the fins 702 and 708 have been recessed down to a level of the STI 712. Specifically, the STI 712 is a layer on the substrate 706 on both sides of the fins 702 and 708, and the fins 702 and 708 are recessed to a height corresponding to a level of the top surface of the STI 712. Thus, at the fabrication stage shown in FIG. 7D, only the dummy gates 714 and channel regions 702C and 708C of the fins 702 and 708 extend above the level of the STI 712.

FIG. 7E illustrates a fabrication stage in the process 600 of forming a first P-type epi-S/D 724 on the first fin 702 and a second P-type epi-S/D 726 on the second fin 708 (block 604), respectively, of the FinFET circuit 700 in FIG. 7D. The P-type epi-S/Ds 724 and 726 may have, for example, a crystalline structure formed of epitaxial SiGe or another semiconductor material doped with boron (B) or another material. In the cross-sectional view at line E-E′, the P-type epi-S/Ds 724 and 726 extend up from the recessed fins 702 and 708 above the STI 712.

FIG. 7F illustrates the fabrication stage of forming a protective layer 728 having a first thickness on the first P-type epi-S/D 724 and the first thickness on the second P-type epi-S/D 726 (block 606) of the FinFET circuit 700 in FIG. 7E. As shown in the cross-sectional view at line F-F′, the protective layer 728 may also be formed on the STI 712. The protective layer 728 may also be referred to herein, alone or in combination with at least one other layer, as a boundary layer.

FIG. 7G illustrates a fabrication stage of forming a mask 730 covering the first P-type epi-S/D 724 and exposing a portion (726S) of the second P-type epi-S/D 726 of the FinFET circuit 700 in FIG. 7F (block 608). The mask 730 is formed as a layer covering the protective layer 728 on the first P-type epi-S/D 724 and the second P-type epi-S/D 726. A portion of the mask 730 is removed such that the remaining mask 730 extends continuously over the first P-type epi-S/D 724 and over at least a portion of the second P-type epi-S/D 726, such that an end surface 730E is formed over the second P-type epi-S/D 726. In addition, FIG. 7G illustrates the fabrication stage of removing portions of the protective layer 728 not covered by the mask 730 to expose the portion 726S of the second P-type epi-S/D 726 (block 610). In particular, FIG. 7G illustrates removing portions of the protective layer 728 on the second P-type epi-S/D 726 that are not covered by the mask 730 to expose the exposed portion 726S of the second P-type epi-S/D 726. The cross-sectional view taken at line G-G′ illustrates the end surface 730E of the mask 730 aligned over the second P-type epi-S/D 726 on the second fin 708 such that the mask 730 covers at least some, but not all, of the second P-type epi-S/D 726. The end surface 730E is positioned within an acceptable range of variation, which corresponds to the dashed lines D4-D6 in FIG. 4A. With the end surface 730E as shown, no defects will be created. Portions of the protective layer 728 that are not under the mask 730 and not under the second P-type epi-S/D 726 are removed. Accordingly, a portion 726S of a surface of the second P-type epi-S/D 726 is exposed.

FIG. 7H illustrates a fabrication stage of removing the second P-type epi-S/D 726 from within a remaining structure 728R of the protective layer 728 above the second fin 708 (block 612) in the FinFET circuit 700 in FIG. 7G. In particular, removing the second P-type epi-S/D 726 may include selectively etching the second P-type epi-S/D 726. The protective layer 728 protects the first P-type epi-S/D 724 from the process for removing the second P-type epi-S/D 726. Where a portion of the protective layer 728 was removed, as shown FIG. 7G, the exposed portion 726S of the second P-type epi-S/D 726 in FIG. 7G was exposed to, for example, a chemical etch process that removed the second P-type epi-S/D 726 from the second fin 708 within the remaining structure 728R of the protective layer 728. In addition, the fabrication stage illustrated in FIG. 7H includes removing the mask 730, leaving at least one end of the remaining structure 728R.

FIG. 7I is a perspective view of the FinFET circuit 700 taken at the cross-section at line H-H′ in the plan view of FIG. 7H. FIG. 7 illustrates the remaining structure 728R of the protective layer 728 that remains over the second fin 708 after removal of the second P-type epi-S/D 726, and also shows the first P-type epi-S/D 724 protected by the protective layer 728 that was under the mask 730. The remaining structure 728R of the protective layer 728 may be coupled to and structurally supported, at least at one end, by attachment to the dummy gate 714. The channel region 708C, which will be a channel region of an NFET, will be electrically coupled to an N-type epi-S/D that will be formed on the second fin 708, which has been recessed. A corresponding structure, not visible in FIG. 7, will be formed on the opposite side of the dummy gate 714 on another recessed portion of the second fin 708.

FIG. 7J illustrates a fabrication stage of the exemplary process 600 of forming an N-type epi-S/D 732 on the second fin 708 within the remaining structure 728R of the protective layer 728 above the second fin 708 (block 614). The cross-sectional view taken at line J-J′ corresponds to the cross-sectional view taken at line H-H′ in FIG. 7H. The N-type epi-S/D 732 may be formed of silicon doped with arsenic (As) or phosphorous (P) or another material, for example.

FIG. 7K illustrates a fabrication stage of forming an etch stop layer 734 over the protective layer 728 on the first P-type epi-S/D 724 and the N-type epi-S/D 732, and over a portion of the N-type epi-S/D 732 not covered by the protective layer 728 (block 616) in the FinFET circuit 700 in FIG. 7J. The etch stop layer 734 together with the protective layer 728 may be referred to herein as a boundary layer 736 on the first P-type epi-S/D 724 and the N-type epi-S/D 732. The cross-sectional view taken at line K-K′ in FIG. 7K shows that a thickness of the boundary layer 736 over both of the first P-type epi-S/D 724 and the N-type epi-S/D 732 includes a thickness of the protective layer 728 and a thickness of the etch stop layer 734.

FIG. 7L illustrates a fabrication stage of forming an ILD 738 over the etch stop layer 734 on the first P-type epi-S/D 724 and the N-type epi-S/D 732 (block 618) in the FinFET circuit 700 in FIG. 7K. As shown in the cross-sectional views taken at lines L1-L1′ and L2-L2′, a height of the ILD 738 may correspond to a height of the hard mask 720 of the dummy gates 714. The height of the ILD 738 may be set by depositing the ILD 738 to a height greater than that of the dummy gates 714 and performing a chemical mechanical polish (CMP) to reduce the height of the ILD 738 to the height of the dummy gates 714.

FIG. 7M illustrates a fabrication stage of forming gate cuts in the dummy gate 714 in the FinFET circuit 700 in FIG. 7L. More specifically, as shown in the cross-sectional view taken at line M-M′, a portion of each of the hard mask 720, the dummy layer 718, and the oxide 716 are removed and replaced by a gate cut fill 740 between the first P-type epi-S/D 724 and the N-type epi-S/D 732. The gate cut fill 740 provides electrical isolation between respective conductive gates (formed later).

FIG. 7N illustrates a fabrication stage of removing the hard mask 720 from the dummy layer 718 of the dummy gate 714 in the FinFET circuit 700 in FIG. 7M. As shown in the cross-sectional view taken at line N-N′ compared to FIG. 7M, a top portion of the gate cut fill 740 corresponding to a thickness of the hard mask 720 is also removed.

FIG. 7O illustrates a fabrication stage of removing the dummy layer 718 and the oxide 716 in the FinFET circuit 700 in FIG. 7N, as shown in the cross-section taken at line O-O′. The plan view in FIG. 7O shows that the gate spacers 722, which were formed on side walls 714W of the dummy gates 714, are not removed by this fabrication stage. The cross-sectional view taken at line O-O′ illustrates that the gate cut fill 740 stays in place between the channel regions 702C and 708C of the first fin 702 and the second fin 708.

FIG. 7P illustrates a fabrication stage of forming replacement metal gates (RMGs) 742 on the first P-type epi-S/D 724 and the N-type epi-S/D 732 in a space between the gate spacers 722 in the FinFET circuit 700 in FIG. 7O as shown in the cross-section taken at line P-P′. The RMGs 742 include a high-K layer 742H formed directly on the channel regions 702C and 708C of the first fin 702 and the second fin 708. The RMGs 742 may be formed of metal or another conductive material 742C formed over the high-K layer 742H.

FIG. 7Q illustrates a fabrication stage of recessing the RMGs 742 and forming a sacrificial layer 744 on the conductive material 742C in the FinFET circuit 700 in FIG. 7P as shown in the cross-section taken at line Q-Q′. The sacrificial layer 744 may include SiN, for example. The FinFET circuit 700 may be resurfaced by a CMP process, for example, such that a height of the sacrificial layer 744 corresponds to a height of the ILD 738.

FIG. 7R illustrates a fabrication stage of forming a contact ILD 746 on the FinFET circuit 700 in FIG. 7Q, as shown in the cross-section taken at line R-R′. The contact ILD 746 is formed over the ILD 738 and the sacrificial layer 744.

FIG. 7S illustrates a fabrication stage of forming a first void 748P in the contact RD 746 and the ILD 738 over the first P-type epi-S/D 724 (block 620) in the FinFET circuit 700 in FIG. 7R, as shown in the cross-section taken at line S-S′. The fabrication stage illustrated in FIG. 7S further includes removing a portion of the etch stop layer 734 and a portion of the protective layer 728 below the first void 748P to expose a contact portion 724C of the first P-type epi-S/D 724 (block 622). The fabrication stage illustrated in FIG. 7S further includes forming a second void 748N in the contact ILD 746 and the ILD 738 over the N-type epi-S/D 732 (block 624). The fabrication stage illustrated in FIG. 7S further includes removing a portion of the etch stop layer 734 below the second void 748N to expose a contact portion 732C of the N-type epi-S/D 732 (block 626).

FIG. 7T illustrates a fabrication stage of filling the first void 748P and the second void 748N with conductive material 750 to form electrical contacts 752P and 752N to the first P-type epi-S/D 724 and the N-type epi-S/D 732, respectively (block 628). Forming the electrical contacts 752P and 752N may further include forming a liner 754 in each of the first void 748P and the second void 748N before filling the first void 748P and the second void 748N with conductive material 750. As shown in the cross-section taken at line T-T′, the FinFET circuit 700 in FIG. 7T may be the FinFET circuit 400 in FIG. 4B.

By employing the exemplary process illustrated in FIGS. 6A-6B and 7A-7T of forming an N-type epi-S/D by replacing a P-type epi-S/D, vulnerability to process variation is reduced compared to the conventional method. To better understand distinguishing aspects of the disclosed exemplary process, a more detailed explanation of a conventional process is provided with reference to cross-sectional views 8A-8G which are similar to FIGS. 2, 3A-1, 3A-2, 3B-1, and 3B-2 taken at line Z-Z′ of FinFET circuit 100 in FIG. 1. FIGS. 8A-8F illustrate subsequent fabrication stages, such as the fabrication stages illustrated in FIGS. 2, 3A-1, 3A-2, 3B-1, and 3B-2.

FIG. 8A illustrates a fabrication stage in which a gate spacer 802, corresponding to the gate spacer 204 in FIG. 2, is formed over a fin 804 in an N-type diffusion region 806. In addition, a P-type epi-S/D 808, corresponding to the P-type epi-S/D 202 of FIG. 2, is formed on a fin 810 in a P-type diffusion region 812 of a substrate 814, which corresponds to the substrate 110 in the FinFET circuit 100 in FIG. 1.

FIG. 8B illustrates a fabrication stage in which a blocking layer 816 is formed over the P-type epi-S/D 808 and the gate spacer 802.

FIG. 8C illustrates the fabrication stage shown in FIG. 2, in which a mask 818 is formed to have an end surface 818E in an acceptable range of variation within which defects are not formed. The acceptable range of variation in FIG. 8C is between dashed lines D7 and D9, where D7 is aligned with an end point of the blocking layer 816 on the P-type epi-S/D 808, D9 is aligned with the blocking layer 816 on the fin 804, and D8 is at the center of an acceptable range of variation between dashed lines D7 and D9. As discussed above with respect to FIG. 2, if the end surface 818E of the mask 818 is aligned to the right side of the dashed line D9, extending over the blocking layer 816 on the fin 804, residual portions of the blocking layer 816 may not be removed. Such residual portions may interfere with formation of an N-type epi-S/D on the fin 804. If the end surface 818E of the mask 818 is aligned to the left side of the dashed line D7, overlapping the blocking layer 816, and possibly also the P-type epi-S/D 808, a portion of the P-type epi-S/D 808 may be exposed during formation of the N-type epi-S/D on the fin 804, creating an undesired electrical connection (i.e., a short defect) between a PFET and an NFET to be formed on the fins 804 and 810. Thus, from the dashed line D8, the maximum acceptable variation in one direction is, for example, the distance 819 from dashed line D8 to dashed line D7.

The conventional process is vulnerable to short defects due to the narrow acceptable range of variation between the dashed lines D7 and D9. As technology advances, it is desirable to reduce a distance between adjacent fins in a FinFET circuit. Thus, the short defect vulnerability of the conventional process will become a bigger problem.

Resuming the description of the conventional process, FIG. 8D illustrates a fabrication stage in which the gate spacer 802 has been removed and the blocking layer 816 has been removed from areas not covered by the mask 818. In addition, the fin 804 has been recessed compared to the circuit in FIG. 8C. FIG. 8E illustrates formation of an N-type epi-S/D 822 on the fin 804 without a short defect. FIG. 8E also shows that the mask 818 has been removed. FIG. 8F illustrates the formation of an etch stop layer 824, deposition of an ILD 826, and formation of contacts 828.

FIG. 8G is an illustration of the FinFET circuit 700 in FIG. 7T formed by the exemplary process 600 disclosed herein. FIGS. 8F and 8G are presented side-by-side for comparison to ease identification of a distinguishing aspect. In particular, in the conventional process in FIG. 8F, both of the etch stop layer 824 and the blocking layer 816 are between the P-type epi-S/D 808 and the ILD 826, but only the etch stop layer 824 is between the N-type epi-S/D 822 and the ILD 826. In contrast, in the FinFET circuit 700, both of the first P-type epi-S/D 724 and the N-type epi-S/D 732 have the protective layer 728 and the etch stop layer 734 formed thereon. Because the N-type epi-S/D 732 is formed by a replacement process, within the remaining structure 728R of the protective layer 728, both the protective layer 728 and the etch stop layer 734 are between the N-type epi-S/D 732 and the ILD 738. Therefore, the FinFET circuit 700 in FIGS. 7T and 8G includes a boundary layer 736 having a thickness between the ILD 738 and the first P-type epi-S/D 724 and having the thickness (i.e., the same thickness) between the ILD 738 and the N-type epi-S/D 732.

In the embodiment shown in FIGS. 4B and 7T, which are based on the exemplary process 600, the protective layer 728 and the etch stop layer 734 together form a boundary layer 736 over the first P-type epi-S/D 724 and the N-type epi-S/D 732. FIGS. 9A and 9B are a flowchart illustrating a process 900 of another particular aspect of the process 600. The process 900 is described below with reference to fabrication stages of a FinFET circuit 1000 illustrated in FIGS. 10A-10Q. Each of the FIGS. 10A-10Q includes an illustration of a plan view of the FinFET circuit 1000 and at least one illustration of a cross-sectional view of a portion of the FinFET circuit 1000, similar to FIGS. 7A-7T.

FIG. 10A is an illustration of a fabrication stage of the FinFET circuit 1000 in the process 900. FIG. 10A includes a cross-sectional view taken at line A-A′ of the plan view of FinFET circuit 1000, corresponding to the fabrication stage illustrated in FIG. 7C. As shown in FIG. 10A, the process 900 includes forming a first fin 1002 extending from a P-type diffusion region 1004 of a substrate 1006 and a second fin 1008, substantially parallel to the first fin 1002, extending from an N-type diffusion region 1010 of the substrate 1006 (block 902). The first fin 1002 and the second fin 1008 may be referred to hereinafter as the fin 1002 and the fin 1008. FIG. 10A also shows a gate spacer 1012, which is a layer formed on vertical and horizontal surfaces of the first fin 1002 and the second fin 1008 in the FinFET circuit 1000.

FIG. 10B illustrates a fabrication stage in which the gate spacer 1012 is removed (e.g., etched away) from horizontal surfaces of the FinFET circuit 1000 and remains on side walls 1014W of dummy gates 1014. The cross-sectional view taken at line B-B′ of the plan view in FIG. 10B shows that the fins 1002 and 1008 have been recessed down to a level of a STI 1016.

FIG. 10C illustrates a fabrication stage in the process 900 of forming a first P-type epi-S/D 1018 on the first fin 1002 and a second P-type epi-S/D 1020 on the second fin 1008 (block 904), respectively, of the FinFET circuit 1000 in FIG. 10B.

FIG. 10D illustrates the fabrication stage of forming an etch stop layer 1022 having a first thickness on the first P-type epi-S/D 1018 and having the first thickness on the second P-type epi-S/D 1020 (block 906) of the FinFET circuit 1000 in FIG. 10C. The etch stop layer 1022 is also formed on the STI 1016. The etch stop layer 1022 may also be referred to in this aspect of the disclosed process as a boundary layer. In addition, the fabrication stage illustrated in FIG. 10D includes forming an ILD 1024 over the etch stop layer 1022 on the first P-type epi-S/D 1018 on the first fin 1002 and on the second P-type epi-S/D 1020 on the second fin 1008 (block 908).

FIG. 10E illustrates a fabrication stage in the process 900 of forming a mask 1026 on the ILD 1024, the mask 1026 having an opening 1028 over the second P-type epi-S/D 1020 (block 910) of the FinFET circuit 1000 in FIG. 10D. The fabrication stage illustrated in FIG. 10E further includes forming a first void 1030 in the ILD 1024 from the opening 1028 in the mask 1026 down to the second P-type epi-S/D 1020 (block 912) in the FinFET circuit 1000. The fabrication stage illustrated in FIG. 10E also includes removing a portion of the etch stop layer 1022 on the second P-type epi-S/D 1020 below the first void 1030 (block 914) in the FinFET circuit 1000. The first void 1030 in the ILD 1024 and the portion of the etch stop layer 1022 on the second P-type epi-S/D 1020 may be removed separately or in a single process.

FIG. 10F illustrates a fabrication stage in the process 900, as shown in the cross-section taken at line F-F′ of removing the second P-type epi-S/D 1020 from within a remaining structure 1022R of the etch stop layer 1022 (block 916) of the FinFET circuit 1000 in FIG. 10E. The mask 1026 is also removed. The second P-type epi-S/D 1020 may be removed by a selective etch process, for example. After removal of the second P-type epi-S/D 1020, the remaining structure 1022R of the etch stop layer 1022 remains inside the ILD 1024.

FIG. 10G illustrates a fabrication stage in the process 900, as shown in the cross-section taken at line G-G′, of forming an N-type epi-S/D 1032 on the second fin 1008 within the remaining structure 1022R of the etch stop layer 1022 above the second fin 1008 (block 918) in the FinFET circuit 1000 in FIG. 10F. Forming the N-type epi-S/D 1032 may include growing the N-type epi-S/D 1032 on the second fin 1008 below the first void 1030 in the ILD 1024.

FIG. 10H illustrates a fabrication stage in the process 900, as shown in the cross-section taken at line H-H′, of forming an etch stop patch 1034 on the N-type epi-S/D 1032 below the first void 1030 in the ILD 1024 (block 920) in the FinFET circuit 1000 in FIG. 10G.

FIG. 10I illustrates a fabrication stage in the process 900 including, as shown in the cross-section taken at line I-I′, filling the first void 1030 in the ILD 1024 with ILD material 1036 (block 922) above the etch stop patch 1034.

FIG. 10J illustrates a fabrication stage of forming gate cuts 1038 in the dummy gates 1014 in the FinFET circuit 1000 in FIG. 10I. More specifically, as shown in the cross-sectional view taken at line J-J′, a portion of each of a hard mask 1040, a dummy layer 1042, and an oxide 1044 are removed from the gate cut 1038 and replaced by a gate cut fill 1046. The gate cut fill 1046 electrically isolates portions of conductive gates formed over channel regions 1002C and 1008C of the first fin 1002 and the second fin 1008, respectively.

FIG. 10K illustrates a fabrication stage of removing the hard mask 1040 from the dummy gates 1014 in the FinFET circuit 1000 in FIG. 10J. As shown in the cross-sectional view taken at line K-K′, a top portion of the gate cut fill 1046 corresponding to a thickness of the hard mask 1040 is also removed.

FIG. 10L illustrates a fabrication stage of removing the dummy layer 1042 and the oxide 1044 in the FinFET circuit 1000 in FIG. 10K, as shown in the cross-section taken at line L-L′. The plan view in FIG. 10L shows the gate spacers 1012 formed on side walls 1014W of the dummy gates 1014, which are not removed in this fabrication stage. The cross-sectional view taken at line L-L′ illustrates that the gate cut fill 1046 stays in place between the first fin 1002 and the second fin 1008.

FIG. 10M illustrates a fabrication stage of forming RMGs 1048 on the first fin 1002 and the second fin 1008 in a space between the gate spacers 1012 in the FinFET circuit 1000 in FIG. 10L as shown in the cross-section taken at line M-M′. The RMGs 1048 include a high-K layer 1048H formed directly on the first fin 1002 and the second fin 1008. The RMGs 1048 may be formed of metal or another conductive material 1048C on the high-K layer 1048H.

FIG. 10N illustrates a fabrication stage of recessing the RMGs 1048 and forming a sacrificial layer 1050 in the FinFET circuit 1000 in FIG. 10M as shown in the cross-section taken at line N-N′. The FinFET circuit 1000 may be resurfaced by a CMP process, for example, such that a height of the sacrificial layer 1050 corresponds to a height of the ILD 1024.

FIG. 10O illustrates a fabrication stage of forming a contact ILD 1052 over the FinFET circuit 1000 in FIG. 10N, as shown in the cross-section taken at line O-O′.

FIG. 10P illustrates a fabrication stage of forming a second void 1054P in the contact ILD 1052 and the ILD 1024 over the first P-type epi-S/D 1018 (block 924) in the FinFET circuit 1000 in FIG. 10O, as shown in the cross-section taken at line P-P′. The fabrication stage illustrated in FIG. 10P further includes removing a portion of the etch stop layer 1022 below the second void 1054P to expose a contact portion 1018C of the first P-type epi-S/D 1018 (block 926). The fabrication stage illustrated in FIG. 10P further includes forming a third void 1054N in the ILD 1024 over the N-type epi-S/D 1032 (block 928). The fabrication stage illustrated in Figure OP further includes removing a portion of the etch stop patch 1034 and/or the etch stop layer 1022 below the third void 1054N to expose a contact portion 1032C of the N-type epi-S/D 1032 (block 930).

FIG. 10Q illustrates a fabrication stage of filling the second void 1054P and the third void 1054N with conductive material 1056 to form electrical contacts 1056P and 1056N to the first P-type epi-S/D 1018 and the N-type epi-S/D 1032, respectively (block 932) as shown in the cross-section taken at line Q-Q′.

FIG. 11A is a copy of the cross-sectional view shown in FIG. 8F of a circuit according to the conventional process. FIG. 11B is the FinFET circuit 1000 in FIG. 10Q. FIGS. 11A and 11B are presented side-by-side for comparison to ease identification of a distinguishing aspect. In particular, in the cross-sectional view according to the conventional process in FIG. 11A, the etch stop layer 824 and the blocking layer 816 are between the P-type epi-S/D 808 and the ILD 826. Only the etch stop layer 824 is between the N-type epi-S/D 822 and the ILD 826. In contrast, because the N-type epi-S/D 1032 in FIG. 11B is formed by a replacement process within the remaining structure 1022R of the etch stop layer 1022, only the etch stop layer 1022 is between the N-type epi-S/D 1032 and the ILD 1024. Thus, in the FinFET circuit 1000, each of the first P-type epi-S/D 1018 and the N-type epi-S/D 1032 are separated from the ILD by only the etch stop layer 1022. Therefore, the FinFET circuit 1000 in FIGS. 10Q and 11B includes a boundary layer (e.g., etch stop layer 1022) having a thickness between the ILD 1024 and the first P-type epi-S/D 1018 and having the thickness (i.e., the same thickness) between the ILD 1024 and the N-type epi-S/D 1032.

A FinFET circuit including an N-type epi-S/D formed on a fin in an N-type diffusion region of a substrate substantially parallel to a P-type epi-S/D on a fin in a P-type diffusion region with a barrier to formation of N-type epi material on the P-type epi-S/D that reduces vulnerability to short defects due to mask variation, as illustrated in any of FIGS. 4B, 7T, 10Q, and 11B according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

In this regard, FIG. 12 illustrates an example of a processor-based system 1200 including a FinFET circuit including an N-type epi-S/D formed on a fin in an N-type diffusion region of a substrate substantially parallel to a P-type epi-S/D on a fin in a P-type diffusion region with a barrier to formation of N-type epi material on the P-type epi-S/D that reduces vulnerability to short defects due to mask variation, including, but not limited to, the circuits in FIGS. 4B, 7T, 10Q, and 11B, and according to any aspects disclosed herein. In this example, the processor-based system 1200 includes one or more central processor units (CPUs) 1202, which may also be referred to as CPU or processor cores, each including one or more processors 1204. The CPU(s) 1202 may have cache memory 1206 coupled to the processor(s) 1204 for rapid access to temporarily stored data. As an example, the processor(s) 1204 could include a FinFET circuit including an N-type epi-S/D formed on a fin in an N-type diffusion region of a substrate substantially parallel to a P-type epi-S/D on a fin in a P-type diffusion region with a barrier to formation of N-type epi material on the P-type epi-S/D that reduces vulnerability to short defects due to mask variation, including, but not limited to, the circuits in FIGS. 4B, 7T, 10Q, and 11B, and according to any aspects disclosed herein. The CPU(s) 1202 is coupled to a system bus 1208 and can intercouple master and slave devices included in the processor-based system 1200. As is well known, the CPU(s) 1202 communicates with these other devices by exchanging address, control, and data information over the system bus 1208. For example, the CPU(s) 1202 can communicate bus transaction requests to a memory controller 1210 as an example of a slave device. Although not illustrated in FIG. 12, multiple system buses 1208 could be provided, wherein each system bus 1208 constitutes a different fabric.

Other master and slave devices can be connected to the system bus 1208. As illustrated in FIG. 12, these devices can include a memory system 1212 that includes the memory controller 1210 and one or more memory arrays 1214, one or more input devices 1216, one or more output devices 1218, one or more network interface devices 1220, and one or more display controllers 1222, as examples. Each of the memory system 1212, the one or more input devices 1216, the one or more output devices 1218, the one or more network interface devices 1220, and the one or more display controllers 1222 can include a FinFET circuit including an N-type epi-S/D formed on a fin in an N-type diffusion region of a substrate substantially parallel to a P-type epi-S/D on a fin in a P-type diffusion region with a barrier to formation of N-type epi material on the P-type epi-S/D that reduces vulnerability to short defects due to mask variation, as illustrated in any of FIGS. 4B, 7T, 10Q, and 11B, and according to any aspects disclosed herein. The input device(s) 1216 can include any type of input device, including, but not limited to, input keys, switches, voice processors, etc. The output device(s) 1218 can include any type of output device, including, but not limited to, audio, video, other visual indicators, etc. The network interface device(s) 1220 can be any device configured to allow exchange of data to and from a network 1224. The network 1224 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1220 can be configured to support any type of communications protocol desired.

The CPU(s) 1202 may also be configured to access the display controller(s) 1222 over the system bus 1208 to control information sent to one or more displays 1226. The display controller(s) 1222 sends information to the display(s) 1226 to be displayed via one or more video processors 1228, which process the information to be displayed into a format suitable for the display(s) 1226. The display(s) 1226 can include any type of display, including, but not limited to, a cathode ray tube (CRT), a liquid crystal display (LCD), a plasma display, a light emitting diode (LED) display, etc. The display controller(s) 1222, display(s) 1226, and/or the video processor(s) 1228 can include a FinFET circuit including an N-type epi-S/D formed on a fin in an N-type diffusion region of a substrate substantially parallel to a P-type epi-S/D on a fin in a P-type diffusion region with a barrier to formation of N-type epi material on the P-type epi-S/D that reduces vulnerability to short defects due to mask variation, as illustrated in any of FIGS. 4B, 7T, 10Q, and 11B, and according to any aspects disclosed herein.

FIG. 13 illustrates an exemplary wireless communications device 1300 that includes radio frequency (RF) components formed from an IC 1302, wherein any of the components therein can include a FinFET circuit including an N-type epi-S/D formed on a fin in an N-type diffusion region of a substrate substantially parallel to a P-type epi-S/D on a fin in a P-type diffusion region with a barrier to formation of N-type epi material on the P-type epi-S/D that reduces vulnerability to short defects due to mask variation, as illustrated in any of FIGS. 4B, 7T, 10Q, and 11B, and according to any aspects disclosed herein. The wireless communications device 1300 may include or be provided in any of the above-referenced devices, as examples. As shown in FIG. 13, the wireless communications device 1300 includes a transceiver 1304 and a data processor 1306. The data processor 1306 may include a memory to store data and program codes. The transceiver 1304 includes a transmitter 1308 and a receiver 1310 that support bi-directional communications. In general, the wireless communications device 1300 may include any number of transmitters 1308 and/or receivers 1310 for any number of communication systems and frequency bands. All or a portion of the transceiver 1304 may be implemented on one or more analog ICs, RF ICs (RFICs), mixed-signal ICs, etc.

The transmitter 1308 or the receiver 1310 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1310. In the direct-conversion architecture, a signal is frequency-converted between RF and baseband in one stage. The super-heterodyne and direct-conversion architectures may use different circuit blocks and/or have different requirements. In the wireless communications device 1300 in FIG. 13, the transmitter 1308 and the receiver 1310 are implemented with the direct-conversion architecture.

In the transmit path, the data processor 1306 processes data to be transmitted and provides I and Q analog output signals to the transmitter 1308. In the exemplary wireless communications device 1300, the data processor 1306 includes digital-to-analog converters (DACs) 1312(1), 1312(2) for converting digital signals generated by the data processor 1306 into the I and Q analog output signals, e.g., I and Q output currents, for further processing.

Within the transmitter 1308, lowpass filters 1314(1), 1314(2) filter the I and Q analog output signals, respectively, to remove undesired signals caused by the prior digital-to-analog conversion. Amplifiers (AMPs) 1316(1), 1316(2) amplify the signals from the lowpass filters 1314(1), 1314(2), respectively, and provide I and Q baseband signals. An upconverter 1318 upconverts the I and Q baseband signals with I and Q transmit (TX) local oscillator (LO) signals through mixers 1320(1), 1320(2) from a TX LO signal generator 1322 to provide an upconverted signal 1324. A filter 1326 filters the upconverted signal 1324 to remove undesired signals caused by the frequency upconversion as well as noise in a receive frequency band. A power amplifier (PA) 1328 amplifies the upconverted signal 1324 from the filter 1326 to obtain the desired output power level and provides a transmitted RF signal. The transmitted RF signal is routed through a duplexer or switch 1330 and transmitted via an antenna 1332.

In the receive path, the antenna 1332 receives signals transmitted by base stations and provides a received RF signal, which is routed through the duplexer or switch 1330 and provided to a low noise amplifier (LNA) 1334. The duplexer or switch 1330 is designed to operate with a specific receive (RX)-to-TX duplexer frequency separation, such that RX signals are isolated from TX signals. The received RF signal is amplified by the LNA 1334 and filtered by a filter 1336 to obtain a desired RF input signal. Downconversion mixers 1338(1), 1338(2) mix the output of the filter 1336 with I and Q RX LO signals (i.e., LO_I and LO_Q) from an RX LO signal generator 1340 to generate I and Q baseband signals. The I and Q baseband signals are amplified by amplifiers (AMPs) 1342(1), 1342(2) and further filtered by lowpass filters 1344(1), 1344(2) to obtain I and Q analog input signals, which are provided to the data processor 1306. In this example, the data processor 1306 includes Analog to Digital Converters (ADCs) 1346(1), 1346(2) for converting the analog input signals into digital signals to be further processed by the data processor 1306.

In the wireless communications device 1300 of FIG. 13, the TX LO signal generator 1322 generates the I and Q TX LO signals used for frequency upconversion, while the RX LO signal generator 1340 generates the I and Q RX LO signals used for frequency downconversion. Each LO signal is a periodic signal with a particular fundamental frequency. A TX phase-locked loop (PLL) circuit 1348 receives timing information from the data processor 1306 and generates a control signal used to adjust the frequency and/or phase of the TX LO signals from the TX LO signal generator 1322. Similarly, an RX PLL circuit 1350 receives timing information from the data processor 1306 and generates a control signal used to adjust the frequency and/or phase of the RX LO signals from the RX LO signal generator 1340.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but, is to be accorded the widest scope consistent with the principles and novel features disclosed herein.

What is claimed is:

1. A Fin Field-Effect Transistor (FinFET) circuit, comprising:
a first fin extending from a substrate in a P-type region of the substrate;
a second fin extending from the substrate in an N-type region of the substrate, the second fin substantially parallel to the first fin;
a P-type epitaxial (epi) Source/Drain (S/D) (epi-S/D) on the first fin;
an N-type epi-S/D on the second fin;
an Inter-Layer Dielectric (ILD) material over the P-type epi-S/D and the N-type epi-S/D; and
a boundary layer having a thickness between the ILD material and the P-type epi-S/D and having the thickness between the ILD material and the N-type epi-S/D.

2. The FinFET circuit of claim 1, wherein:
a first side of the boundary layer is in contact with the ILD material and a second side of the boundary layer is in contact with the P-type epi-S/D and the N-type epi-S/D.

3. The FinFET circuit of claim 1, further comprising:
a first contact through the ILD material electrically coupled to a portion of the N-type epi-S/D not covered by the boundary layer; and
a second contact through the ILD material electrically coupled to a portion of the P-type epi-S/D not covered by the boundary layer.

4. The FinFET circuit of claim 1, wherein the P-type epi-S/D and the N-type epi-S/D are separated by at least a first portion of the boundary layer on the P-type epi-S/D and a second portion of the boundary layer on the N-type epi-S/D.

5. The FinFET circuit of claim 1, wherein the boundary layer consists of an etch stop layer.

6. The FinFET circuit of claim 1, wherein the boundary layer comprises:
a protective layer; and
an etch stop layer.

7. The FinFET circuit of claim 6, wherein:
the protective layer is directly on the N-type epi-S/D and the P-type epi-S/D; and
the etch stop layer is between the protective layer and the ILD material.

8. The FinFET circuit of claim 1 integrated in an integrated circuit (IC).

9. The FinFET circuit of claim 1, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

10. A method of forming an N-type epitaxial (epi) source/drain (S/D) (epi-S/D) on a fin of an N-type Fin Field-Effect Transistor (FinFET) (NFET) substantially parallel to a P-type epi-S/D on a fin of a P-type FinFET (PFET) in a FinFET circuit, comprising:
forming a first fin extending from a P-type region of a substrate and a second fin, substantially parallel to the first fin, extending from an N-type region of the substrate;
forming a first P-type epi-S/D on the first fin and a second P-type epi-S/D on the second fin;
forming a boundary layer on the first P-type epi-S/D and on the second P-type epi-S/D;
removing portions of the boundary layer to expose a portion of the second P-type epi-S/D;
removing the second P-type epi-S/D from within a remaining structure of the boundary layer above the second fin; and
forming an N-type epi-S/D on the second fin within the remaining structure of the boundary layer above the second fin.

11. The method of claim 10, wherein removing the second P-type epi-S/D further comprises selectively etching the second P-type epi-S/D.

12. The method of claim 10, further comprising:
forming a shallow trench isolation (STI) on the substrate between the first fin and the second fin; and
recessing the first fin and the second fin to a level of the STI before forming the first P-type epi-S/D on the first fin and the second P-type epi-S/D on the second fin.

13. The method of claim 10, wherein removing the portions of the boundary layer further comprises:
forming a mask covering the first P-type epi-S/D and covering at least a portion of the second P-type epi-S/D; and
removing portions of the boundary layer on the second P-type epi-S/D not covered by the mask to expose the portion of the second P-type epi-S/D.

14. The method of claim 13, wherein forming the mask covering the first P-type epi-S/D and covering at least the portion of the second P-type epi-S/D further comprises:
forming the mask covering the boundary layer on the first P-type epi-S/D and the second P-type epi-S/D; and
removing a portion of the mask from the second P-type epi-S/D such that an end surface of the mask is aligned over the second P-type epi-S/D.

15. The method of claim 10, further comprising:
forming a dummy gate over the first fin extending from the P-type region of the substrate and over the second fin extending from the N-type region of the substrate; and
forming a gate spacer on a side wall of the dummy gate;
wherein one end of the remaining structure of the boundary layer is coupled to the gate spacer on the side wall of the dummy gate.

16. The method of claim 10, wherein:
the boundary layer comprises a protective layer; and
the method further comprising:
forming an etch stop layer over the protective layer on the first P-type epi-S/D and on the N-type epi-S/D and over a portion of the N-type epi-S/D not covered by the protective layer; and
forming an inter-layer dielectric (ILD) over the etch stop layer on the first P-type epi-S/D on the first fin and on the N-type epi-S/D on the second fin.

17. The method of claim 16, further comprising:
forming a first void in the ILD over the first P-type epi-S/D;
removing a portion of the etch stop layer and a portion of the protective layer below the first void to expose a contact portion of the first P-type epi-S/D;
forming a second void in the ILD over the N-type epi-S/D;
removing a portion of the etch stop layer below the second void and any portion of the protective layer below the second void to expose a contact portion of the N-type epi-S/D; and
filling the first and second voids with conductive material to form electrical contacts to the first P-type epi-S/D and the N-type epi-S/D.

18. The method of claim 10, wherein:
the boundary layer comprises an etch stop layer; and
the method further comprising:
forming an inter-layer dielectric (ILD) over the etch stop layer on the first P-type epi-S/D on the first fin and on the second P-type epi-S/D on the second fin.

19. The method of claim 18, wherein removing the portions of the boundary layer to expose the portion of the second P-type epi-S/D further comprises:
forming a mask on the ILD, the mask having an opening over the second P-type epi-S/D;
forming a first void in the ILD from the opening to the second P-type epi-S/D; and
removing a portion of the etch stop layer on the second P-type epi-S/D below the first void.

20. The method of claim 19, further comprising:
filling the first void in the ILD with ILD material;
forming a second void in the ILD over the first P-type epi-S/D;
removing a portion of the etch stop layer below the second void to expose a contact portion of the first P-type epi-S/D;
forming a third void in the ILD over the N-type epi-S/D;
removing a portion of the etch stop layer below the second void to expose a contact portion of the N-type epi-S/D; and
filling the second and third voids with conductive material to form electrical contacts to the first P-type epi-S/D and the N-type epi-S/D.
